(19) United States
(12) Patent Application Publication
(10) Pub. No.: US 2023/0037857 A1
(43) Pub. Date: Feb. 9, 2023

(54) BATTERY CHARGE DETERMINATION

(71) Applicant: HEWLETT-PACKARD DEVELOPMENT COMPANY, L.P., Spring, TX (US)

(72) Inventor: Melody Autumn THAI, Vancouver, WA (US)

(21) Appl. No.: 17/792,683

(22) PCT Filed: Mar. 31, 2020
(86) PCT No.: PCT/US2020/025991

§ 371 Date: Jul. 13, 2022

(51) Int. Cl. G01R 31/388; H02J 7/00

(52) U.S. Cl. CPC G01R 31/388; H02J 7/0048

(57) ABSTRACT

A device includes a battery, a voltage sensor, and a controller. The battery includes a first discharge rate between a first voltage and a second voltage and a second discharge rate between the second voltage and a third voltage. The second voltage is less than the first voltage and the third voltage is less than the second voltage. The voltage sensor is to sense a voltage of the battery. The controller is to convert the sensed voltage of the battery to a percentage value indicating a remaining charge of the battery as a linear function based on time to discharge the battery from the first voltage to the third voltage.

### BACKGROUND

Devices may be powered by batteries. To reduce the cost of devices, those devices may be powered by cheaper batteries that provide less information than more sophisticated batteries.

### BRIEF DESCRIPTION OF THE DRAWINGS

FIG. 1 is a block diagram illustrating one example of a device to determine a remaining charge of a battery.

FIG. 2 is a chart illustrating one example of battery voltage percentage over time and battery life percentage over time for an example battery.

FIG. 3 is a block diagram illustrating another example of a device to determine a remaining charge of a battery.

FIG. 4 is a flow diagram illustrating one example of a method to indicate the remaining charge of a battery.

### DETAILED DESCRIPTION

The remaining charge of a battery may be determined based on the voltage of the battery in some examples. A battery, however, may include a first discharge rate when the battery is fully charged and a second discharge rate when the battery is close to discharged. Therefore, the voltage reading is a nonlinear indication of the remaining charge. The remaining charge, however, may not be an accurate representation of the remaining time of operation of a battery or corresponding device.

Accordingly, disclosed herein are devices and methods that convert the voltage reading of a battery to a percentage value indicating the remaining charge of the battery as a linear function of the time to discharge the battery from a maximum voltage to a shutdown voltage. The conversion from the voltage reading to the battery life percentage may be based on the first discharge rate, the second discharge rate, and the voltage reading.

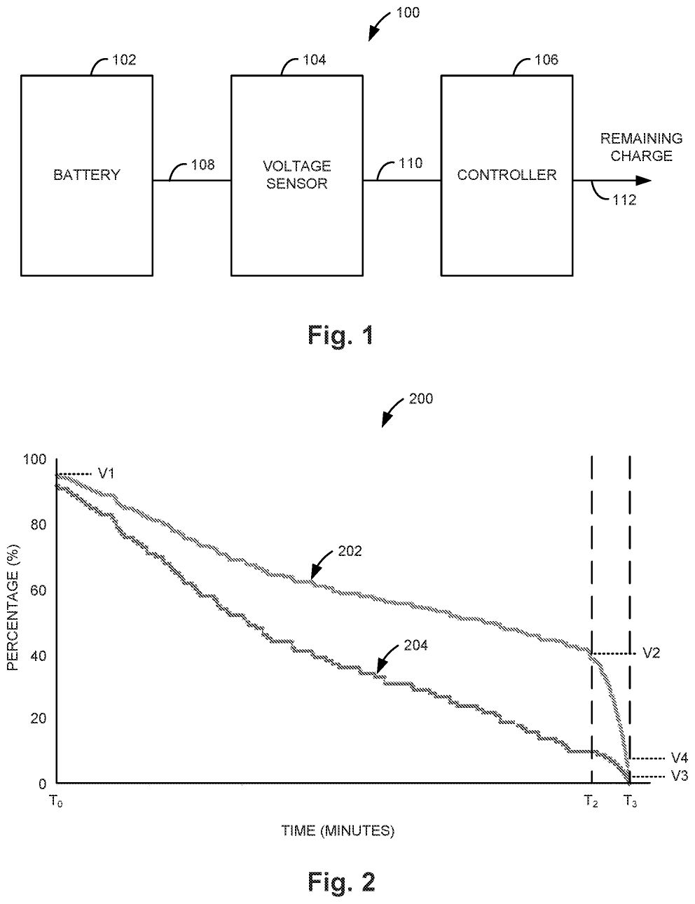

FIG. 1 is a block diagram illustrating one example of a device 100 to determine a remaining charge of a battery. Device 100 includes a battery 102, a voltage sensor 104, and a controller 106. Battery 102 is electrically coupled to an input of voltage sensor 104 through a signal path 108. An output of voltage sensor 104 is electrically coupled to an input of controller 106 through a signal path 110. Controller 106 outputs a remaining charge signal on a signal path 112. In one example, battery 102 is a lithium-ion battery or another suitable type of battery.

FIG. 2 is a chart 200 illustrating one example of battery voltage percentage over time as indicated at 202 and battery life percentage over time as indicated at 204 for an example battery, such as battery 102 of FIG. 1. The 0 percent and 100 percent indicated on the y-axis corresponds to a minimum (e.g., shutoff) voltage and a maximum voltage of the battery, respectively. Referring to both FIGS. 1 and 2, battery 102 includes a first discharge rate between a first voltage V1 and a second voltage V2 and a second discharge rate between the second voltage V2 and a third voltage V3. The second voltage V2 is less than the first voltage V1, and the third voltage V3 is less than the second voltage V2. In one example, the third voltage V3 is a battery shutdown voltage. The first discharge rate between the first voltage V1 and the second voltage V2 is slower than the second discharge rate between the second voltage V2 and the third voltage V3. In one example, the second discharge rate is at least five times faster than the first discharge rate. In another example, the difference between the first voltage V1 and the second voltage V2 is greater than the difference between the second voltage V2 and the third voltage V3. While described generally as having two discharge rates, depending on the battery and device characteristics, there could be additional discharge rates for additional charge ranges of a battery. For example, there could be an initial relatively high discharge rate, followed by a relatively lower discharge rate, that then converts into a relatively high discharge rate again at a lower voltage.

Voltage sensor 104 senses the voltage of the battery 102 through the signal path 108. Voltage sensor 104 may include an analog to digital converter and/or other suitable circuitry for sensing the analog voltage of the battery 102 and converting the analog voltage to a digital value. Voltage sensor 104 may pass the digital value of the sensed voltage to controller 106 through the signal path 110.

Controller 106 may include a central processing unit (CPU), a microprocessor, a microcontroller, an application-specific integrated circuit (ASIC), and/or other suitable logic circuitry. Controller 106 converts the sensed voltage of the battery 102 from voltage sensor 104 to a percentage value indicating a remaining charge of the battery as a linear function based on the time to discharge the battery 102 from the first voltage V1 to the third voltage V3, as indicated by the battery life percentage at 204. In one example, controller 106 calculates the first discharge rate and the second discharge rate each time the battery is fully recharged (e.g., when the sensed voltage is greater than or equal to the first voltage V1 and/or when a maximum charge of the battery is detected). As described in more detail below, controller 106 may determine the first voltage V1 in response to the battery 102 being fully charged, determine the first discharge rate based on the first voltage V1 and the second voltage V2, determine the second discharge rate based on the second voltage V2 and the third voltage V3, and determine a percentage value indicating a remaining charge of the battery 102 as a linear function based on the sensed voltage of the battery 102, the first discharge rate, the second discharge rate, and the second voltage V2. The second voltage V2, the third voltage V3, and the fourth voltage V4 may be constants based on the battery 102.

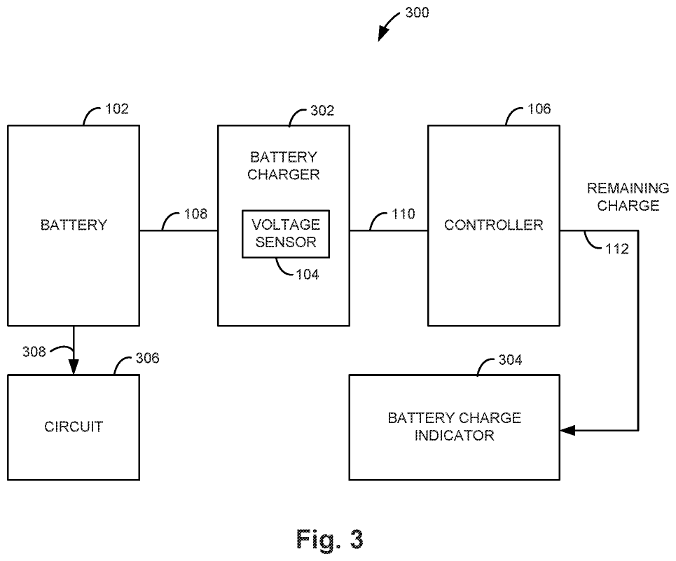

FIG. 3 is a block diagram illustrating another example of a device 300 to determine a remaining charge of a battery. Device 300 is similar to device 100 previously described and illustrated with reference to FIG. 1. Device 300 also includes a battery charger 302, a battery charge indicator 304, and a circuit 306 in addition to battery 102, voltage sensor 104, and controller 106. An output of battery 102 is electrically coupled to circuit 306 through a signal path 308. An output of controller 106 is electrically coupled to battery charge indicator 304 through signal path 112.

In this example, the voltage sensor 104 is part of the battery charger 302. Battery charger 302 may be used to recharge battery 102 via a power source (not shown), such as an AC power source. In one example, battery charger 302 may be a battery charging integrated circuit.

Battery charge indicator 304 receives the remaining charge signal from controller 106 through signal path 112. In response to the remaining charge signal, battery charge indicator 304 outputs a visual, textual, and/or audible indication corresponding to the remaining charge signal. In one example, battery charge indicator 304 may include a multicolor display (e.g., multicolor LED), which varies in color based on the remaining charge signal, such as green for a full charge (e.g., above 19% charge remaining), yellow for a low charge (e.g., between 19% and 5% charge remaining), and red for a very low charge (e.g., less than 4% charge remaining). In another example, battery charge indicator 304 may include a text display to display the remaining charge as a percentage. In yet another example, battery charge indicator 304 may include a speaker to output a first sound/tone when the battery charge is low and/or a second sound/tone when the battery charge is very low. In other examples, battery charge indicator 304 may include other suitable indicators, such as visual bars indicating the remaining charge.

Circuit 306 may be powered by battery 102 through signal path 308. Referring back to FIG. 2, in one example circuit 306 may stop operating at a fourth voltage V4 between the second voltage V2 and the third voltage V3. The fourth voltage V4 may be set to a constant percentage value (e.g., 4%) of the remaining charge of the battery 102.

Controller 106 may execute instructions (e.g., firmware) stored in a memory (not shown) communicatively coupled to controller 106. The instructions may use the following variables.

V_max_hw: Maximum specified voltage of the battery 102.

V_max_actual: Actual (measured) maximum voltage of the battery 102 when fully charged. This maximum voltage may be measured by battery charger 302 after a full recharge. In FIG. 2, the first voltage V1 may be V_max_actual.

V_low: Low voltage threshold of the battery 102 as a percentage. The low voltage threshold may be used to change the indication output by the battery charge indicator 304. V_low is a constant for the life of the battery 102.

V_LRC: Voltage life rate change of the battery. This value may be derived by controller 106 after the battery 102 is fully recharged and by monitoring the voltage percentage over time prior to putting the battery into service. This value is the voltage point where the rate of change in the voltage over time changes from a slower rate to a faster decreasing rate. In FIG. 2, the second voltage level V2 may be V_LRC. V_LRC is a constant for the life of the battery 102.

V_dead: Voltage at which the battery is considered to be dead (e.g., insufficient charge to operate circuit 306). Both the voltage and the percentage may be fixed. This value may be used to convert between the battery voltage percentage over time (e.g., 202 of FIG. 2) and the battery life percentage over time (e.g., 204 of FIG. 2). The value for V_dead may be determined by the power draw of the circuit 306. In FIG. 2, the fourth voltage V4 may be V_dead. V_dead is greater than or equal to V_shutdown_hw described below. At or above V_dead, the circuit 306 can perform all functions. Below V_dead, some or all of the functions of circuit 306 cannot be performed. Below V_dead, controller 106 and battery charge indicator 304 may still be functional and the controller 106 may output the remaining charge signal to the battery charge indicator 304. V_dead is a constant for the life of the battery 102.

V_shutdown: Voltage at which the device (including controller 106) fully shuts down. This value may be calculated each time the battery 102 is fully recharged. A check may be done to ensure V_shutdown is greater than or equal to V_shutdown_hw plus a predetermined buffer value (e.g., 100 mV). V_shutdown could be equal to V_shutdown_hw, but having a buffer ensures that the controller 106 can shut down the device properly instead of a forced hardware shutdown. In FIG. 2, V_shutdown may be between the third voltage V3 and the fourth voltage V4.

V_shutdown_hw: Specified voltage at which the battery shuts down. This value is a hardware/physical limitation. The hardware/battery will shut itself down at this voltage. In FIG. 2, the third voltage V3 may be V_shutdown_hw. V_shutdown_hw is a constant for the life of the battery 102.

T_LRC_2_dead: Calculated time in minutes between V_LRC and V_dead for the device. In FIG. 2, this time may be between T₂ and the time at the fourth voltage V4. T_LRC_2_dead may be determined prior to putting the battery 102 into service by drawing a constant current from the battery. Once determined, T_LRC_2_dead is a constant for the life of the battery 102.

T_slow_rate_max: Calculated time in minutes between V_max_hw and V_LRC for the device prior to placing the device into service. In FIG. 2, this time may be between T₀ and T₂. T_slow_rate_max is determined prior to putting the battery 102 into service by drawing a constant current from the battery. Once determined, T_slow_rate_max is a constant for the life of the battery 102.

T_slow: Calculated time in minutes between V_max_actual and V_LRC. This value may be recalculated each time the battery is fully recharged whenever V_max_actual changes. In FIG. 2, this time may be between T₀ and T₂.

T_fast: Calculated time in minutes between V_LRC and V_shutdown. This value may be recalculated each time the battery is fully recharged whenever V_max_actual changes. In FIG. 2, this time may be between T₂ and T₃.

Percent_dead: Battery life percentage when the voltage of the battery is at V_dead. This value may be recalculated each time the battery is fully recharged whenever V_max_actual changes.

Percent_LRC: Battery life percentage when the voltage of the battery is at V_LRC. This value may be recalculated each time the battery is fully recharged whenever V_max_actual changes.

Some of the above values may be obtained from measurements (either directly or indirectly). To convert from a battery voltage percentage (e.g., 202 of FIG. 2) to a battery life percentage (e.g., 204 of FIG. 2) that is linear to time, time constants are used. These values may or may not be provided by the battery specification. If these values are not provided by the battery specification, they may be obtained by monitoring the device while the device is in an idle state (e.g., the battery is drawing a constant current) until either the instructions (e.g., firmware) or the hardware shuts down due to the battery voltage being too low. The times T₀, T₂, and T₃ are determined prior to putting the battery into service and are used as constants throughout the life of the battery.

The two values calculated to enable the transformation from a battery voltage percentage to a linear battery life percentage are T_LRC_2_dead and T_slow_rate_max. Because the battery voltage percentage over time is divided into two regions, slow slope (higher voltages) and fast slope (lower voltages), and one straight line equation is used for each of these regions, the times are calculated according to the following equations. These regions are not quite as simple as a straight line, however, treating them as straight lines yields a more linear equation with time with respect to battery life percentage.

First the slopes of the two regions are determined. To determine the slope of either region, V_LRC is first determined. This is the voltage value at which the voltage percentage curve changes from a slow rate of decrease to a fast rate of decrease, i.e. the point where the slope changes. This value may be determined via measurements or provided by the battery specification.

Referring to FIG. 2, the slow slope (m_slow) is calculated as follows:

m_slow=delta_voltage/delta_time

m_slow=(V1−V2)/(T₀−T₂)

Now that m_slow is calculated, T_slow_rate_max is determined. The slopes are constant and equal, so the two slopes of the same line can be set equal to each other as follows:

m_slow=(V_max_hw−V_LRC)/(−T_slow_rate_max)

Then solve for T_slow_rate_max as follows:

T_slow_rate_max=(V_max_hw−V_LRC)/(−m_slow)

T_slow_rate_max can now be considered a constant and used in the instructions (e.g., firmware) and in other equations.

Referring to FIG. 2, the fast slope (m_fast) may be calculated as follows:

m_fast=delta_voltage/delta_time

m_fast=(V2−V3)/(T₂−T₃)

Now that m_fast is calculated, T_LRC_2_dead is determined. The slopes are constant and equal, so the two slopes of the same line can be set equal to each other as follows:

m_fast=(V_dead−V_LRC)/T_LRC_2_dead

Then solve for T_LRC_2_dead as follows:

T_LRC_2_dead=(V_dead−V_LRC)/m_fast

T_LRC_2_dead can now be considered a constant and used in the instructions (e.g., firmware) and in other equations.

The following equations may be used directly by the instructions (e.g., firmware). The equations may be calculated each time the battery is fully charged. Because most batteries do not usually charge up to their maximum voltage that the specification states and because that value may vary after each complete recharge of the battery, the instructions may calculate a few variables at each complete recharge. These variables are used for the battery life percentage transformation. Data from the battery charger 302 may be used by the controller 106 to determine when a complete recharge of the battery has occurred at which point the controller may read the voltage V_max_actual of the battery.

Equation 1 is used to determine the actual time for the slow rate region. Although T_slow_rate_max has been calculated based on V_max_hw, T_slow is now calculated based on V_max_actual. The two slopes of the same line are set equal as follows:

(V_max_hw−V_LRC)/T_slow_rate_max=(V_max_actual−V_LRC)/T_slow

Then solve for T_slow as follows:

T_slow={(V_max_actual−V_LRC)/(V_max_hw−V_LRC)}*T_slow_rate_max Equation 1

This newly calculated value for T_slow can be used to determine the new battery life percentage at V_LRC.

Equation 2 is used to determine the actual time for the fast rate region (T_fast) as follows:

Percent_dead=(T_fast−T_LRC_2_dead)/(T_slow+T_fast)

Then solve for T_fast as follows:

T_fast=(Percent_dead/100*T_slow+T_LRC_2_dead)/(1−Percent_dead/100) Equation 2

Equation 3 is used to determine the battery life percentage at V_LRC. The instructions (e.g., firmware) may recalculate this value whenever V_max_actual changes at each full battery recharge. Battery life percentage is a percentage of the remaining time to the total time as follows:

Percent_LRC=T_fast/(T_slow+T_fast)*100 Equation 3

Equation 4 is used to check Equations 1, 2, and 3. Percent_LRC may be checked to determine whether it is within the hardware limitations. This is because T_fast may be calculated at each complete recharge of the battery. The instructions (e.g., firmware) use this new value, but to allow this transformation, V_shutdown is allowed to fluctuate within this transformation. V_shutdown should still be within the hardware limitations. V_shutdown should be checked to ensure it is greater than or equal to V_shutdown_hw as follows:

(V_max_actual−V_shutdown)/(T_slow+T_fast)=(V_LRC−V_shutdown)/(T_fast−0)

Then solve for V_shutdown as follows:

V_shutdown=(V_LRC−B*V_max_actual)/(1−B)

Where B=T_fast/(T_slow+T_fast)

Thus:

V_shutdown=V_LRC*(T_slow/(T_slow+T_fast))−(T_fast/T_slow)*V_max_actual Equation 4

The instructions (e.g., firmware) may check that this value is within range before continuing. The instructions may check that V_shutdown is greater than or equal to V_shutdown_hw plus a predetermined buffer value (e.g., 100 mV). V_shutdown could be equal to V_shutdown_hw, but having a buffer ensures that the controller 106 can shut down the device properly instead of a forced hardware shutdown.

In one example, V_max_hw may be used in place of V_max_actual in the above equations, such that calculations at each full recharge of the battery could be skipped. In this case, the equations may be calculated once at firmware boot up.

Equations 5 and 6 below may be calculated periodically (e.g., every five seconds). The exact times may be dependent upon other instruction (e.g., firmware) priorities. V_now is the current voltage of the battery 102 obtained from the voltage sensor 104. Both equations 5 and 6 convert the measured voltage to a battery life percentage. From the above calculations, a direct comparison can be made to solve for P_now. P_now is the battery life percentage for the current voltage, V_now.

In one example, if V_now is greater than V_max_actual then P_now equals 99% (not 100% since returning 100% is reserved for when a full charge is reached). If V_now is greater than V_LRC (i.e., in the slow rate region), equation 5 is used. If V_now is less than or equal to V_LRC (i.e., in the fast rate region), equation 6 is used.

P_now=P_LRC+((V_now−V_LRC)*(P_max−P_LRC)/(V_max_actual−V_LRC)) Equation 5

P_now=P_LRC+((V_now−V_LRC)*(P_LRC−P_dead)/(V_LRC−V_dead)) Equation 6

If P_now is less than 0 based on equation 6, P_now may be set equal to 0.

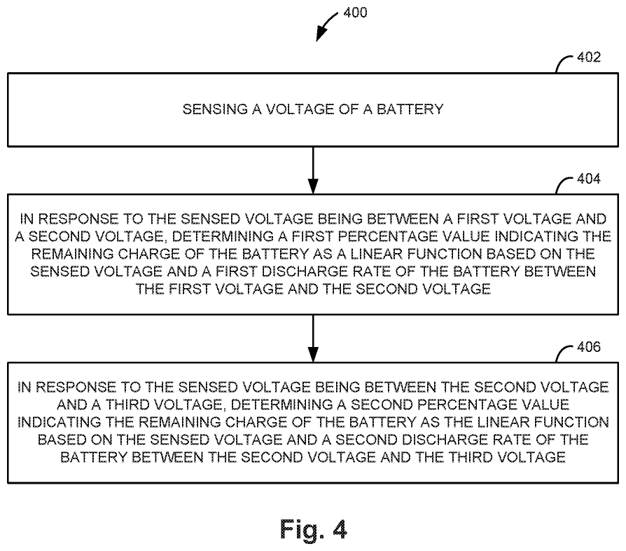

FIG. 4 is a flow diagram illustrating one example of a method 400 to indicate the remaining charge of a battery. In one example, method 400 may be implemented by device 100 previously described and illustrated with reference to FIG. 1 or device 300 previously described and illustrated with reference to FIG. 3. At 402, method 400 includes sensing the voltage of a battery. For example, voltage sensor 104 of FIG. 1 or 3 may sense the voltage of a battery 102.

At 404, method 400 includes in response to the sensed voltage being between a first voltage and a second voltage, determining a first percentage value indicating the remaining charge of the battery as a linear function based on the sensed voltage and a first discharge rate of the battery between the first voltage and the second voltage. For example, controller 106 of FIG. 1 or 3 may in response to the sensed voltage from voltage sensor 104, determine a first percentage value (e.g., 204 of FIG. 2) indicating the remaining charge of the battery 102 as a linear function based on the sensed voltage and a first discharge rate of the battery between the first voltage V1 of FIG. 2 and the second voltage V2 of FIG. 2.

At 406, method 400 includes in response to the sensed voltage being between the second voltage and a third voltage, determining a second percentage value indicating the remaining charge of the battery as the linear function based on the sensed voltage and a second discharge rate of the battery between the second voltage and the third voltage. For example, controller 106 of FIG. 1 or 3 may in response to the sensed voltage from voltage sensor 104 being between the second voltage V2 of FIG. 2 and a third voltage V3 of FIG. 2, determine a second percentage value (e.g., 204 of FIG. 2) indicating the remaining charge of the battery 102 as the linear function based on the sensed voltage and a second discharge rate of the battery between the second voltage V2 of FIG. 2 and the third voltage V3 of FIG. 2.

In one example, method 400 may also include determining the first discharge rate and the second discharge rate each time the battery is fully recharged. For example, controller 106 of FIG. 1 or 3 may determine the first discharge rate and the second discharge rate each time the battery 102 is fully recharged.

In one example, in response to the sensed voltage being between the second voltage and the third voltage, method 400 may also include determining the second percentage value indicating the remaining charge of the battery as the linear function based further on a voltage at which a device powered by the battery stops operating. For example, controller 106 of FIG. 1 or 3 may in response to the sensed voltage from voltage sensor 104 being between the second voltage V2 of FIG. 2 and the third voltage V3 of FIG. 2, determine the second percentage value (e.g., 204 of FIG. 2) indicating the remaining charge of the battery 102 as the linear function based further on a voltage at which a device 100 of FIG. 1 or 300 of FIG. 3 powered by the battery stops operating.

In the preceding detailed description, reference was made to the accompanying drawings which form a part hereof, and in which is shown by way of illustration specific examples in which the disclosure may be practiced. It is to be understood that other examples may be utilized and structural or logical changes may be made without departing from the scope of the present disclosure. The preceding detailed description, therefore, is not to be taken in a limiting sense, and the scope of the present disclosure is defined by the appended claims. It is to be understood that features of the various examples described herein may be combined, in part or whole, with each other, unless specifically noted otherwise.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein.

1. A device comprising:
a battery comprising a first discharge rate between a first voltage and a second voltage and a second discharge rate between the second voltage and a third voltage, the second voltage less than the first voltage and the third voltage less than the second voltage;
a voltage sensor to sense a voltage of the battery; and
a controller to convert the sensed voltage of the battery to a percentage value indicating a remaining charge of the battery as a linear function based on time to discharge the battery from the first voltage to the third voltage.

2. The device of claim 1, wherein the first discharge rate is slower than the second discharge rate.

3. The device of claim 1, wherein the second discharge rate is at least five times faster than the first discharge rate.

4. The device of claim 1, wherein the controller calculates the first discharge rate and the second discharge rate each time the battery is fully recharged.

5. The device of claim 1, wherein the third voltage is a battery shutdown voltage.

6. The device of claim 1, further comprising:
a circuit powered by the battery that stops operating at a fourth voltage between the second voltage and the third voltage.

7. The device of claim 6, wherein the fourth voltage is set to a constant percentage value of the remaining charge of the battery.

8. The device of claim 1, wherein the battery comprises a lithium-ion battery.

9. The device of claim 1, further comprising:
a battery charger,
wherein the voltage sensor is part of the battery charger.

10. A device comprising:
a battery comprising a first discharge rate between a first voltage and a second voltage and a second discharge rate between the second voltage and a third voltage, the second voltage less than the first voltage and the third voltage less than the second voltage;
a voltage sensor to sense a voltage of the battery; and
a controller to determine the first voltage in response to the battery being fully charged, determine the first discharge rate based on the first voltage and the second voltage, determine the second discharge rate based on the second voltage and the third voltage, and determine a percentage value indicating a remaining charge of the battery as a linear function based on the sensed voltage of the battery, the first discharge rate, the second discharge rate, and the second voltage.

11. The device of claim 10, further comprising:
a battery charge indicator to provide an indication of the percentage value.

12. The device of claim 10, wherein the difference between the first voltage and the second voltage is greater than the difference between the second voltage and the third voltage.

13. A method to indicate the remaining charge of a battery, the method comprising:
sensing a voltage of a battery;
in response to the sensed voltage being between a first voltage and a second voltage, determining a first percentage value indicating the remaining charge of the battery as a linear function based on the sensed voltage and a first discharge rate of the battery between the first voltage and the second voltage; and
in response to the sensed voltage being between the second voltage and a third voltage, determining a second percentage value indicating the remaining charge of the battery as the linear function based on the sensed voltage and a second discharge rate of the battery between the second voltage and the third voltage.

14. The method of claim 13, further comprising:
determining the first discharge rate and the second discharge rate each time the battery is fully recharged.

15. The method of claim 13, wherein in response to the sensed voltage being between the second voltage and the third voltage, determining the second percentage value indicating the remaining charge of the battery as the linear function based further on a voltage at which a device powered by the battery stops operating.
